(19) United States
(12) Patent Application Publication
(10) Pub. No.: US 2026/0282232 A1
(43) Pub. Date: Sep. 17, 2026

(54) CIRCUIT BOARD AND IMAGE FORMING APPARATUS

(71) Applicant: CANON KABUSHIKI KAISHA, Tokyo (JP)

(72) Inventor: SHIGETO TANAKA, Chiba (JP)

(21) Appl. No.: 19/561,292

(22) Filed: Mar. 9, 2026

(30) Foreign Application Priority Data
Mar. 13, 2025 (JP) 2025-040346

(51) Int. Cl. H05K 1/181; H04N 1/00; H04N 1/32

(52) U.S. Cl. CPC H05K 1/181; H04N 1/00278; H04N 1/32571; H05K 2201/09227; H05K 2201/09254; H05K 2201/10189; H05K 2201/10212; H05K 2201/10356

(57) ABSTRACT

A circuit board includes a first connector mounted on a surface of the circuit board, a second connector mounted on the surface, and a wiring pattern connected to the first connector and the second connector, wherein a length of the first connector along a first direction is longer than a length of the first connector along a second direction perpendicular to the first direction, each of the first direction and the second direction being parallel to the surface, wherein a length of the second connector along the first direction is longer than a length of the second connector along the second direction, and wherein the first connector and the second connector are arranged such that at least a portion of the first connector overlaps at least a portion of the second connector when viewed in projection along the second direction.

### BACKGROUND

### Field of the Technology

The present disclosure relates to a circuit board, particularly, a circuit board to be mounted in an image forming apparatus to which a reading apparatus is connected, such as a copying machine.

### Description of the Related Art

In recent years, circuit boards having two or more connectors are proposed. Japanese Patent Application Laid-open No. 2008-270662 discloses a circuit board mounted in a copying machine. A copying machine is an image forming apparatus that generates a copy of a document by forming an image of the document that is read by an image reading apparatus. Generally, in a configuration of the copying machine, one type of image reading apparatus is connected to the image forming apparatus. In this regard, an image forming apparatus is provided that can selectively connect multiple types of image reading apparatus according to user requirements. In such an image forming apparatus, the user can select an image reading apparatus connected to the image forming apparatus based on at least one of, for example, frequency of use, processing speed, and image quality.

Image reading apparatuses have multiple types of communication interfaces due to differences in communication speed and other factors. Therefore, for an image forming apparatus, it is necessary to provide a communication interface corresponding to the image reading apparatus to be connected. The image forming apparatus has a circuit board equipped with a connector to which a cable compatible with the communication interface is connected. Japanese Patent Application Laid-open No. 2008-270662 discloses a configuration in which connectors are provided on both the front surface and the back surface of the circuit board. With this configuration, a single board can support two types of communication interfaces.

In the configuration where connectors are provided on both the front surface and back surface of the circuit board, terminals that transmit the same signal at each connector are connected via through-holes. Such through-holes form stubs. A stub is a wiring branch that branches off from a wiring serving as a signal transmission path. In a transmission line that transmits a high-frequency signal, the stub causes degradation of signal quality.

### SUMMARY

A circuit board according to one embodiment of the present disclosure includes a first connector mounted on a surface of the circuit board, a second connector mounted on the surface, and a wiring pattern connected to the first connector and the second connector, wherein a length of the first connector along a first direction is longer than a length of the first connector along a second direction perpendicular to the first direction, each of the first direction and the second direction being parallel to the surface, wherein a length of the second connector along the first direction is longer than a length of the second connector along the second direction, and wherein the first connector and the second connector are arranged such that at least a portion of the first connector overlaps at least a portion of the second connector when viewed in projection along the second direction.

An image forming apparatus according to another embodiment of the present disclosure includes a printing unit configured to form an image on a sheet and a circuit board, wherein the circuit board includes a first connector mounted on a surface of the circuit board, a second connector mounted on the surface, and a wiring pattern connected to the first connector and the second connector, wherein a length of the first connector along a first direction is longer than a length of the first connector along a second direction perpendicular to the first direction, each of the first direction and the second direction being parallel to the surface, wherein a length of the second connector along the first direction is longer than a length of the second connector along the second direction, and wherein the first connector and the second connector are arranged such that at least a portion of the first connector overlaps at least a portion of the second connector when viewed in projection along the second direction.

An image forming apparatus according to yet another embodiment of the present disclosure includes an image reading unit and a circuit board connected to the image reading unit via a cable, wherein the circuit board includes a first connector mounted on a surface of the circuit board, a second connector mounted on the surface, and a wiring pattern connected to the first connector and the second connector, wherein the cable is connected to one of the first connector or the second connector, wherein a length of the first connector in a first direction along the surface is longer than a length of the first connector in a second direction along the surface, the second direction being perpendicular to the first direction, wherein a length of the second connector in the first direction is longer than a length of the second connector in the second direction, and wherein the first connector and the second connector are arranged such that at least a portion of the first connector overlaps at least a portion of the second connector when viewed in projection along the second direction.

Features of the present disclosure will become apparent from the following description of embodiments with reference to the attached drawings. The following description of embodiments is described by way of example.

### BRIEF DESCRIPTION OF THE DRAWINGS

FIG. 1 is a schematic configuration diagram of an image forming apparatus.

FIG. 2 is an explanatory diagram of a connection configuration.

FIG. 3 is an explanatory diagram of the connection configuration.

FIG. 4 is an exemplary diagram of signals assigned to each pin number.

FIG. 5 is a schematic configuration diagram for illustrating an arrangement of each FFC connector placed in a longitudinal direction.

FIG. 6 is an exemplary view of an eye pattern.

FIG. 7 is an exemplary view of the eye pattern.

FIG. 8 is an exemplary view of the eye pattern.

FIG. 9 is a schematic configuration diagram for illustrating an arrangement of each FFC connector placed in a widthwise direction.

FIG. 10 is a schematic configuration diagram for illustrating an arrangement of each FFC connector placed in the widthwise direction.

FIG. 11 is an explanatory view of a stub in a case where a first image reading apparatus is connected.

FIG. 12 is an explanatory view of a stub in a case where a second image reading apparatus is connected.

FIG. 13 is an exemplary configuration diagram for illustrating an arrangement of FFC connectors positioned offset along the longitudinal direction.

### DESCRIPTION OF THE EMBODIMENTS

Now, description of at least one embodiment of the present disclosure with reference to the accompanying drawings is given.

An image reading apparatus and an image forming apparatus are connected, for example, by a flat cable such as a Flexible Flat Cable (FFC) composed of multiple conductors. When connected by the FFC, an FFC connector capable of connecting the FFC is mounted on a circuit board. The FFC is inserted into and removed from the FFC connector while the circuit board is fixed to sheet metal and a frame provided on the image forming apparatus. With respect to workability in insertion and removal of the FFC, arranging the FFC connector on both sides of the circuit board provides better workability than arranging the FFC connector on one side of the circuit board. Furthermore, if a stub exists in a signal transmission path, the quality of the signal deteriorates. The present embodiment describes an image forming apparatus capable of connecting multiple types of image reading apparatus as an example.

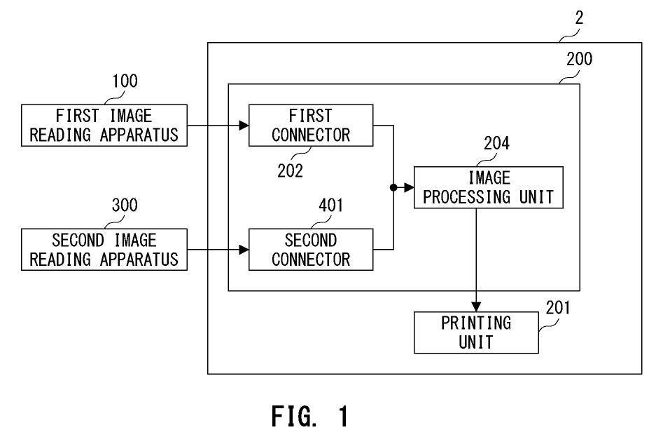

FIG. 1 is a schematic configuration diagram of an image forming apparatus including a circuit board of the present embodiment. Multiple types of image reading apparatuses can be connected to the image forming apparatus 2. In the present embodiment, two types of image reading apparatus (i.e., a first image reading apparatus 100 and a second image reading apparatus 300) can be connected to the image forming apparatus 2. The first image reading apparatus 100 and the second image reading apparatus 300 both read images from a document and transmit image signals representing the read images to the image forming apparatus 2. The first image reading apparatus 100 and the second image reading apparatus 300 differ in at least one of processing speed, reading image quality, communication speed of image signals to the image forming apparatus 2, and communication interface etc., for example.

The image forming apparatus 2 includes a circuit board 200 for acquiring image signals transmitted from the first image reading apparatus 100 and the second image reading apparatus 300, and a printing unit 201 which forms an image on a sheet based on the image signals acquired by the circuit board 200. The printing unit 201 forms images on the sheet using a known method such as electrophotography or inkjet.

The circuit board 200 includes a first connector 202, a second connector 401, and an image processing unit 204. The first connector 202 is connected to a transmission cable that transmits image signals from the first image reading apparatus 100. The second connector 401 is connected to a transmission cable that transmits image signals from the second image reading apparatus 300. In a case where one of the first image reading apparatus 100 and the second image reading apparatus 300 is selectively connected, the other of the first connector 202 and the second connector 401 is in an unconnected state. These transmission cables are flat cables including a plurality of conductors bundled together, for example. In the present embodiment, an example using FFC as the transmission cable will be described. The first connector 202 and the second connector 401 of the present embodiment are elongated FFC connectors. In the FFC connector, multiple terminals are arranged in a longitudinal direction. Hereinafter, the first connector 202 is referred to as "FFC connector 202" and the second connector 401 is referred to as "FFC connector 401".

The image processing unit 204 performs predetermined image processing on the image signals acquired from the first image reading apparatus 100 and the second image reading apparatus 300 to convert them into signals for forming images on the sheet at the printing unit 201. The image processing unit 204 transmits the converted signals to the printing unit 201 to control the printing unit 201 to form images.

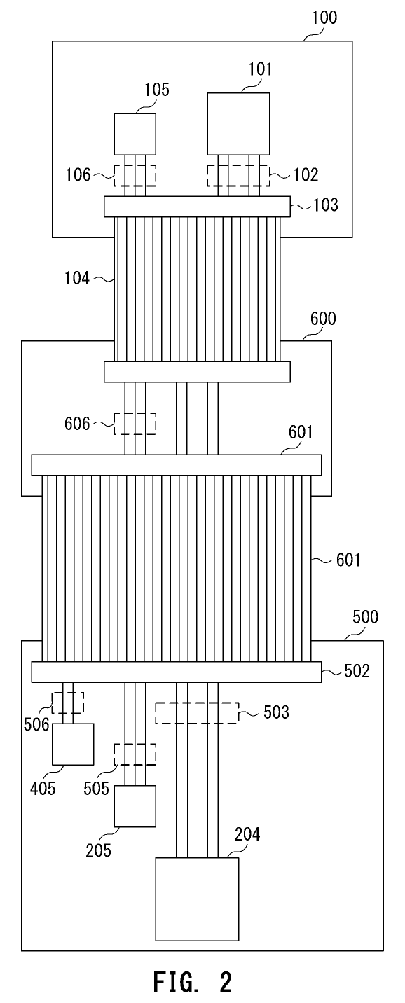

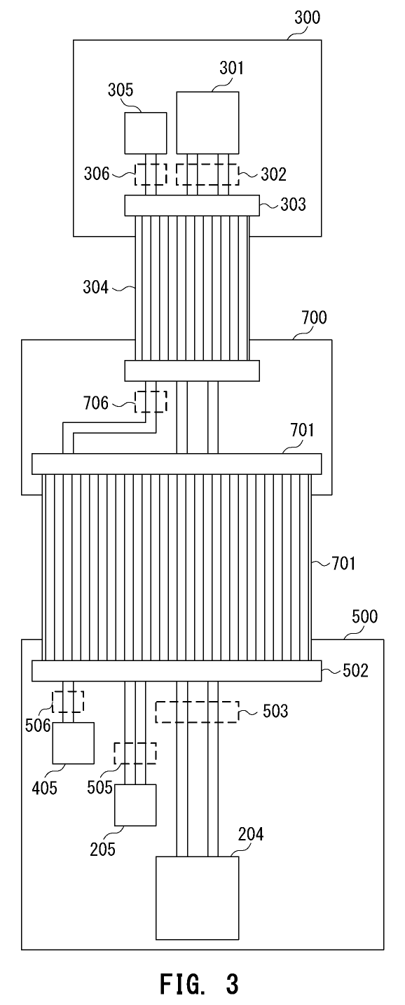

Here, the reason for providing multiple FFC connectors (i.e., FFC connector 202 and FFC connector 401) on the circuit board 200 is explained. FIGS. 2 and 3 are explanatory diagrams of the connection configuration in a case where the first image reading apparatus 100 and the second image reading apparatus 300 are connected individually to the image forming apparatus 2. In FIG. 2, the first image reading apparatus 100 is connected to the image forming apparatus 2 and, in FIG. 3, the second image reading apparatus 300 is connected to the image forming apparatus 2. In this case, a single FFC connector 502 is provided on the circuit board 500 of the image forming apparatus 2.

The first image reading apparatus 100 is connected to a conversion device 600 via an FFC 104. The conversion device 600 is connected to the circuit board 500 of the image forming apparatus 2 via an FFC connector 601. The second image reading apparatus 300 is connected to a conversion device 700 via an FFC 304, and the conversion device 700 is connected to the circuit board 500 of the image forming apparatus 2 via an FFC 701.

In addition to the FFC connector 502 and the image processing unit 204, communication ICs (Integrated Circuits) 205 and 405 are mounted on the circuit board 500. The communication IC 205 performs communication control for three-wire communication (Serial Peripheral Interface (SPI) communication) with the first image reading apparatus 100. The communication IC 405 performs communication control for two-wire communication (Inter-Integrated Circuit (I2C) communication) with the first image reading apparatus 100.

The image processing unit 204 and the FFC connector 502 are connected via the wiring pattern 503. Signals transmitted in common from the first image reading apparatus 100 and the second image reading apparatus 300 are input to the image processing unit 204. Here, image signals are input. The communication IC 205 and the FFC connector 502 are connected via the wiring pattern 505. The communication IC 205 receives signals transmitted only from the first image reading apparatus 100. The communication IC 405 and the FFC connector 502 are connected via the wiring pattern 505. The communication IC 405 receives signals transmitted only from the second image reading apparatus 300.

The first image reading apparatus 100 includes an image processing IC 101, a memory IC 105 that stores values adjusted for each image reading apparatus (such as a light source illumination time), and an FFC connector 103. The image processing IC 101 and the FFC connector 103 are connected via a wiring pattern 102. The memory IC 105 and the FFC connector 103 are connected via a wiring pattern 106. The FFC connector 103 has 12 pins, i.e., the number of terminals (poles) is 12.

The second image reading apparatus 300 includes an image processing IC 301, a memory IC 305 that stores values adjusted for each image reading apparatus (such as a light source illumination time), and an FFC connector 303. The image processing IC 301 and the FFC connector 303 are connected via a wiring pattern 302. The memory IC 305 and the FFC connector 303 are connected by a wiring pattern 306. The FFC connector 303 has 11 pins, i.e., the number of terminals (poles) is 11.

The first image reading apparatus 100 and the second image reading apparatus 300 have different communication interfaces due to differences in communication methods and the number of pins on the FFC connectors. To accommodate this difference, the conversion devices 600 and 700 are used. The conversion devices 600 and 700 have the same configuration, however, the signals acquired from the first image reading apparatus 100 and the second image reading apparatus 300 differ. Thus, some pins of the FFC connector 601 and the FFC connector 701 are assigned different signals.

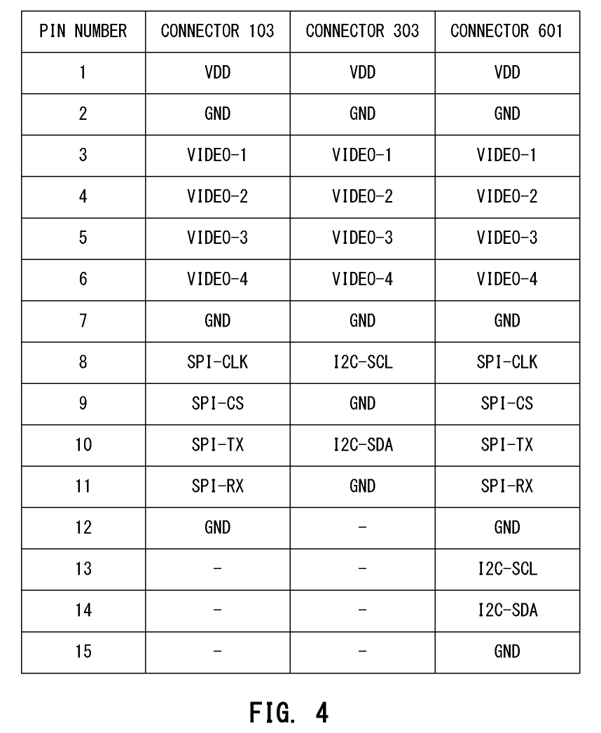

FIG. 4 is an exemplary diagram for illustrating the signals assigned to each pin number of the FFC connector 103, the FFC connector 303, and the FFC connector 601 (701). Signals for pins 1 to 7 are common across each FFC connector. In FIG. 4, VDD indicates the power supply voltage, GND indicates ground, and VIDEO-1, 2, 3, 4 indicate image signals converted to digital signals.

Signals for pins 8 to 12 differ between FFC connector 103 and the FFC connector 303. SPI-CLK, SPI-CS, SPI-TX, and SPI-RX indicate SPI communication signals for communicating with the first image reading apparatus 100. I2C-SCL and I2C-SDA indicate I2C communication signals for communicating with the second image reading apparatus 300.

In order to transmit signals that are not common between the FFC connectors 103 and 303, the number of terminals (pins) of the FFC connectors 601 and 701 is greater than the number of terminals (pins) of FFC connectors 103 and 303. Consequently, the FFC connectors 601 and 701 are longer in the longitudinal direction than FFC connectors 103 and 303. Specifically, the FFC connectors 601 and 701 have terminals (pin numbers 8 to 15) to transmit both the SPI communication signal and the I2C communication signal, which differ between FFC connector 103 and FFC connector 303. This accommodates the difference in communication interfaces between the first image reading apparatus 100 and the second image reading apparatus 300.

Therefore, when arranging, on the circuit board 500, the single FFC connector 502 that can connect either the first image reading apparatus 100 or the second image reading apparatus 300, the conversion devices 600 and 700 are required to accommodate the differences in the communication interfaces. Furthermore, the number of terminals of the FFC connector 502 on the circuit board 500 must be greater than or equal to the number of terminals of the FFC connectors 601 and 701. Consequently, the number of terminals on the FFC connector 502 on the circuit board 500 increases, causing the FFC connector 502 to be longer in the longitudinal direction.

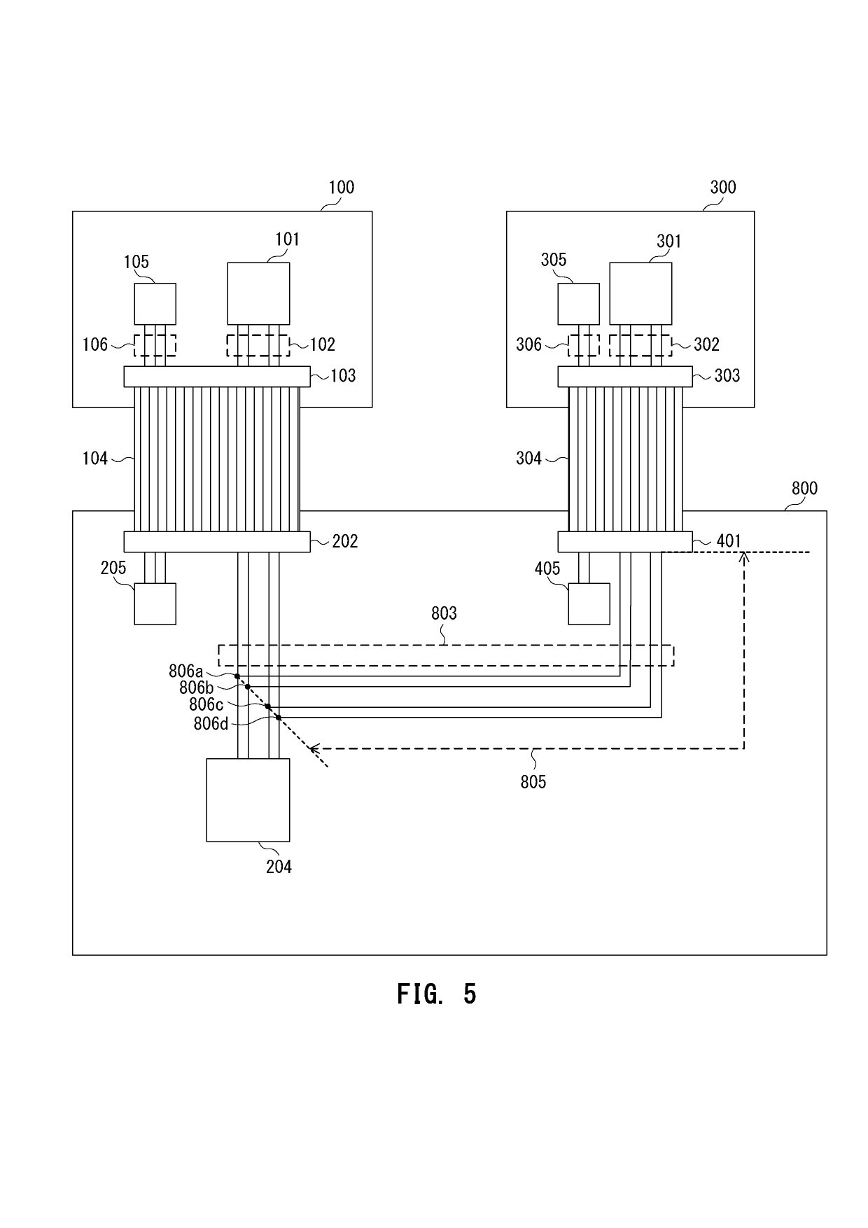

When placing multiple FFC connectors on the circuit board 500, the relative positioning of each FFC connector becomes an issue. FIG. 5 is a schematic configuration diagram for illustrating an arrangement of each FFC connector placed in a longitudinal direction. In FIG. 5, the FFC connector 202 for connecting to the first image reading apparatus 100 and the FFC connector 401 for connecting to the second image reading apparatus 300 are arranged side by side along their longitudinal directions.

In the configuration of FIG. 5, since the FFC connector 202 and the FFC connector 401 are mounted to match the communication interfaces of the first image reading apparatus 100 and the second image reading apparatus 300, respectively, the conversion devices 600 and 700 described in FIGS. 2 and 3 are unnecessary. Consequently, the first image reading apparatus 100 and the second image reading apparatus 300 can each be directly connected to the image forming apparatus 2.

The image signal output from the image processing IC 101 of the first image reading apparatus 100 is input to a circuit board 800 via the wiring pattern 102, the FFC connector 103, the FFC 104, and the FFC connector 202. The image signal is input from the FFC connector 202 to the image processing unit 204 via a wiring pattern 803. Similarly, the image signal output from the image processing IC 301 of the second image reading apparatus 300 is input to the circuit board 800 via the wiring pattern 302, the FFC connector 303, the FFC 304, and the FFC connector 401. The image signal is input to the image processing unit 204 from the FFC connector 401 via the wiring pattern 803.

In the configuration illustrated in FIG. 5, the length of the wiring pattern 803 from the FFC connector 401 to the image processing unit 204 is longer than the length of the wiring pattern 803 from the FFC connector 202 to the image processing unit 204. Furthermore, in the transmission path from the image processing IC 101 to the image processing unit 204, a path 805 from the branching points 806a, 806b, 806c, 806d where the wiring pattern 803 branches to the FFC connector 401 is a redundant wiring pattern (stub). As described above, "stub" is a wiring branch that branches off from a wiring serving as a signal transmission path. Longer stubs may cause impedance mismatch, and may increase signal reflection of the transmission signal. This results in observed jitter, overshoot, undershoot, etc., in the transmission signal, and degrading signal quality. Consequently, the quality of image signals transmitted from the first image reading apparatus 100 deteriorates.

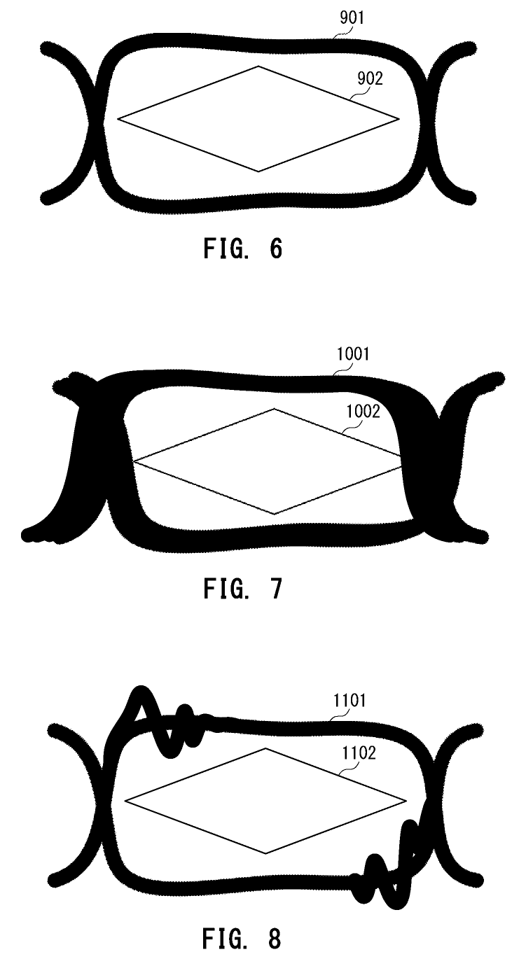

FIGS. 6, 7, and 8 are exemplary views of eye pattern of an image signal transmitted via the wiring pattern 803 in the transmission path from the image processing IC 101 to the image processing unit 204. Here, the eye patterns are illustrated for the case of high-speed transmission of LVDS signals (low-voltage differential signals) as image signals (VIDEO-1, 2, 3, 4). In a case where a signal waveform 901 overlaps a predefined mask 902, 1002, or 1102 of the eye pattern, information of the signal transition may not be transmitted correctly.

In a case where the stub is short and has ideal transmission characteristics, as shown in FIG. 6, the signal waveform 901 does not overlap the predefined mask 902. In a case where the stub is long, as shown in FIG. 7, jitter occurs in the signal due to reflection effects, causing the signal waveform 1001 to overlap the predefined mask 1002. Furthermore, as shown in FIG. 8, overshoot and undershoot occur near the rising and falling edges of signal waveform 1101. Consequently, even if the signal waveform 1001 does not overlap the specified mask 1102 of the eye pattern, distortion occurs, resulting in insufficient margin relative to the predefined mask 1102. Compared to the example shown in FIG. 6, communication errors are more likely to occur in the signal waveforms 1001 and 1101 in FIG. 7 and 8.

Therefore, as shown in FIG. 5, in a case where the FFC connector 202 and the FFC connector 401 are arranged side by side in the longitudinal direction, the stub length in the transmission path from the first image reading apparatus 100 increases, resulting in a degradation of the image signal quality transmitted from the first image reading apparatus 100. For example, this leads to degradation of the image signal transmitted from the first image reading apparatus 100, thereby accurate copying processing may be hindered.

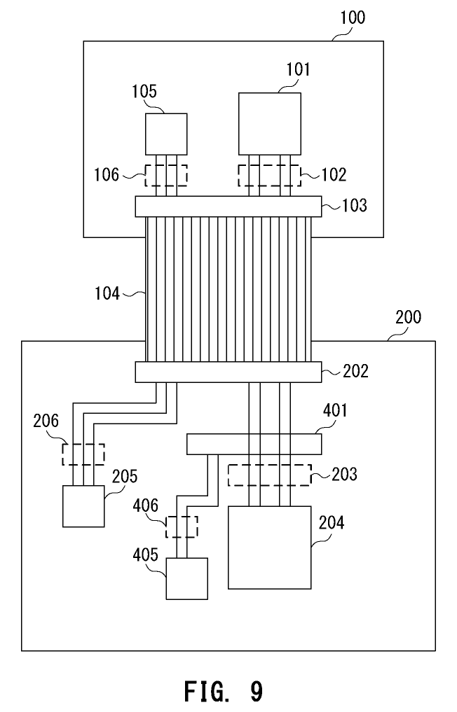

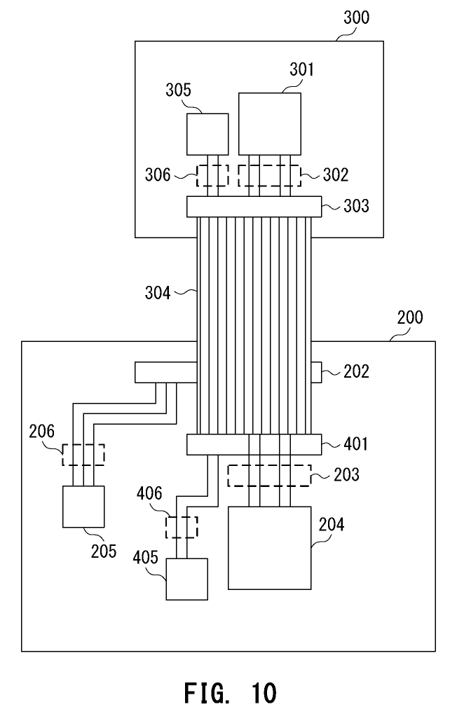

FIGS. 9 and 10 are schematic configuration diagrams for illustrating arrangements of each FFC connector placed in a widthwise direction. Here, the FFC connector 202 and the FFC connector 401 are mounted on the same surface of the circuit board 200. Furthermore, the respective longitudinal direction of the FFC connector 202 and the FFC connector 401 are aligned. Specifically, the longitudinal direction of the FFC connector 202 and the FFC connector 401 are each along a first direction (the left-right direction in FIG. 9). That is, the length of the FFC connector 202 in the first direction (the left-right direction in FIG. 9) is longer than the length of the FFC connector 202 in a second direction (the up-down direction in FIG. 9), which is perpendicular to the first direction. Similarly, the length of the FFC connector 401 in the first direction (left-right direction in FIG. 9) is longer than the length of the FFC connector 401 in the second direction (up-down direction in FIG. 9). It is noted that the first direction and the second direction are each along the mounting surface of the circuit board 200. The FFC connector 202 and the FFC connector 401 are positioned such that at least a portion of them overlap when viewed from the widthwise direction. In other words, when viewed along the second direction (the up-down direction in FIG. 9), the FFC connector 202 and the FFC connector 401 at least partially overlap. Furthermore, in the present embodiment, the FFC connector 202 is mounted closer to an edge of the circuit board 200 than the FFC connector 401. As shown in FIG. 9, a distance along the second direction (the up-down direction in FIG. 9) from the FFC connector 202 to the edge of the circuit board 200 is shorter than the distance along the second direction from the FFC connector 401 to the edge of the circuit board 200. FIG. 9 illustrates an example where the first image reading apparatus 100 is connected to the FFC connector 202 on the circuit board 200. FIG. 10 illustrates an example where the second image reading apparatus 300 is connected to the FFC connector 401 on the circuit board 200.

In FIG. 9, an image signal output from the image processing IC 101 of the first image reading apparatus 100 is input to the circuit board 200 via the wiring pattern 102, the FFC connector 103, the FFC 104, and the FFC connector 202. The FFC 104 is an external cable connecting the FFC connector 103 and the FFC connector 202. The image signal is input from the FFC connector 202 to the image processing unit 204 via the wiring pattern 203. This transmission path has short stubs, making impedance mismatch less likely and suppressing degradation of signal quality in the transmission path.

In FIG. 10, the image signal output from the image processing IC 301 of the second image reading apparatus 300 is input to the circuit board 200 via the wiring pattern 302, the FFC connector 303, the FFC 304, and the FFC connector 401. The FFC 304 is an external cable connecting the FFC connector 303 and the FFC connector 401. The image signal is input from the FFC connector 401 to the image processing unit 204 via the wiring pattern 203. In this transmission path, the wiring pattern 203 from the FFC connector 202 to the FFC connector 401 serves as a stub.

The terminal to which the image signal from the FFC connector 202 is input and the terminal to which the image signal from the FFC connector 401 is input are connected via the same wiring pattern 203. Thus, the image signal acquired from the first image reading apparatus 100 and the image signal acquired from the second image reading apparatus 300 are input to the image processing unit 204 via the same wiring pattern 203.

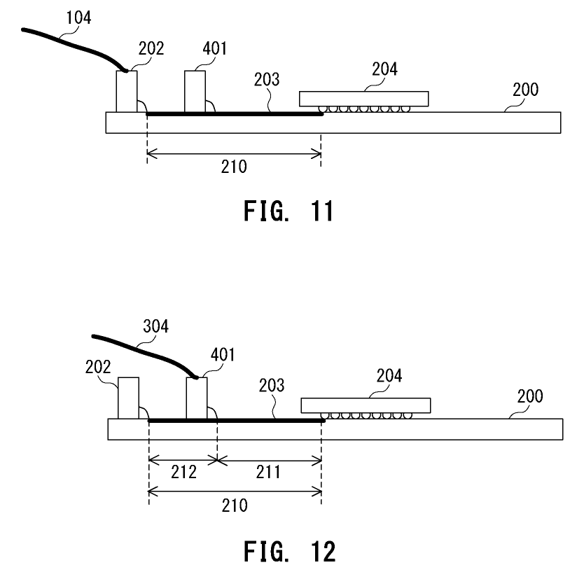

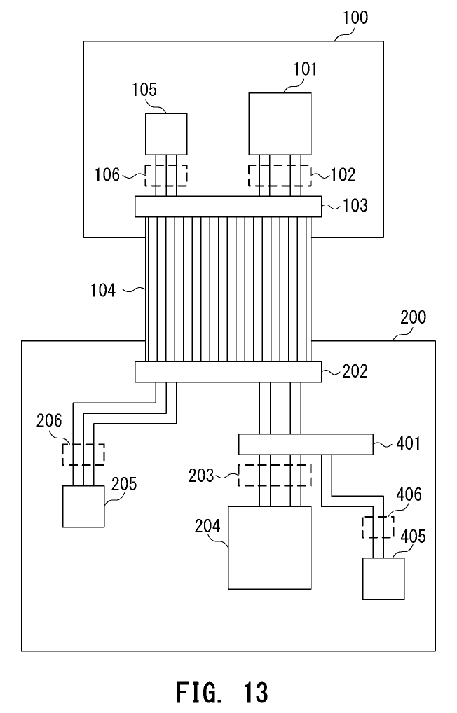

In this configuration, the image signals transmitted from each of the first image reading apparatus 100 and the second image reading apparatus 300 are input to the image processing unit 204 via the same wiring pattern 203. Therefore, the FFC connectors 202 and 401, and the image processing unit 204, are connected via the same wiring pattern 203. However, as to FIG. 9 and FIG. 10, the lengths of the stubs formed by the wiring pattern 203 differ. The differences between the stubs in FIGS. 9 and 10 are explained below. FIG. 11 is an explanatory view of the stub in a case where the first image reading apparatus 100 is connected (FIG. 9). FIG. 12 is an explanatory view of the stub in a case where the second image reading apparatus 300 is connected (FIG. 10). FIGS. 11 and 12 are cross-sectional views of the circuit board 200.

In a case where the first image reading apparatus 100 is connected, the FFC 104 is connected to the FFC connector 202. In FIG. 11, the wiring pattern 203 from the FFC connector 202 to the image processing unit 204 forms the image signal transmission path 210. The transmission path 210 is formed between the FFC connector 202 and the image processing unit 204 via the FFC connector 401. The wiring pattern 203 itself forms the transmission path 210, and no stubs are formed.

In a case where the second image reading apparatus 300 is connected, the FFC 304 is connected to the FFC connector 401. In FIG. 12, the wiring pattern 203 from the FFC connector 401 to the image processing unit 204 forms the image signal transmission path 211. The transmission path 211 is formed between the FFC connector 401 and the image processing unit 204. The wiring pattern 203 between the FFC connector 401 to the FFC connector 202 serves as a stub 212 that is unnecessary for signal transmission via the transmission path 211.

The length of the stub 212 can be shorter than the length of the path 805 which serves as a stub in the configuration of FIG. 5. That is, compared to the configuration shown in FIG. 5 where FFC connectors are arranged in the longitudinal direction, the configurations shown in FIGS. 9 and 10 where FFC connectors are arranged in the width direction allows the stub to be shorter for wiring.

In a case where the frequency of the transmitted signal is high, the stub length affects signal quality. Thus, an image reading apparatus having a high-speed communication interface is connected to an FFC connector with a short stub. In the present embodiment, the communication speed of the first image reading apparatus 100 is faster than that of the second image reading apparatus 300. Therefore, the FFC 104 to be connected to the first image reading apparatus 100 is connected to the FFC connector 202, which has a shorter stub in the transmission path. This suppresses degradation in the signal quality of the image signal transmitted at high speed from the first image reading apparatus 100.

Thus, the FFC connector to which the image reading apparatus is connected is determined based on the length of the stub in the transmission path and the communication speed. In the present embodiment, as described above, the stub length of the transmission line formed by the FFC connector 202 is shorter than the length of the stub 212 formed by the FFC connector 401. The communication speed of the first image reading apparatus 100 is higher than that of the second image reading apparatus 300. Therefore, the first image reading apparatus 100 having a higher communication speed is connected to the FFC connector 202, while the second image reading apparatus 300 having a lower communication speed is connected to the FFC connector 402.

As described above, in the present embodiment, the FFC connector 202 and the FFC connector 401 are arranged on the circuit board 200 of the image forming apparatus 2 such that their respective longitudinal directions are parallel. Furthermore, the FFC connector 202 and the FFC connector 401 are arranged such that at least portions thereof overlap each other when viewed from the widthwise direction. In this configuration, as compared to a case where the FFC connector 202 and the FFC connector 401 are arranged side-by-side in the longitudinal direction, the stub in transmission path can be shorter. Furthermore, the stub in the transmission path of the FFC connector 202 is shorter than the stub 212 in the transmission path of the FFC connector 401.

In a case where the image signal transmission frequencies differ between the first image reading apparatus 100 and the second image reading apparatus 300, the image reading apparatus having a higher image signal transmission speed is connected to the FFC connector 202 having the shorter stub. This connection configuration suppresses degradation in the quality of the transmitted image signal even at higher transmission frequencies. Since the FFC connectors 202 and 401 are mounted on the same side of the circuit board 200. Thus, the ease of inserting and removing the FFCs 104 and 304 into the FFC connectors 202 and 204 is better than a case where the FFC connectors 202 and 401 are mounted on different sides of the circuit board 200.

Although the present embodiment describes a configuration in which the FFC connectors 202 and 401 are mounted on the circuit board 200 of the image forming apparatus 2, the connectors are not limited to the FFC connectors. The type of the connector to be used may be determined according to the type of cable to be connected. The connectors may be, for example, FPC (Flexible Printed Circuit) connectors, board-to-board connectors for connecting circuit boards, connectors for thin coaxial cables, or other connectors used for transmitting image signals.

In FIGS. 9 and 10, the FFC connectors 202 and 401 are arranged such that their ends in the longitudinal direction (the rightmost end in FIGS. 9 and 10) align. In this case, the entire length of the FFC connector 401, which is shorter than the FFC connector 202 in the longitudinal direction, overlaps the FFC connector 202 when viewed from the widthwise dimension. The arrangement of the FFC connectors 202 and 401 is not limited to the above described configuration. For each FFC connector 202, 401, if terminals receiving the same type of signal (in this case, image signals) are arranged to overlap in the widthwise direction, other configurations may also be employed.

FIG. 13 is an exemplary configuration diagram for illustrating an arrangement of the FFC connectors 202 and 401 positioned with an offset along the longitudinal direction. In this case, the FFC connector 202 and the FFC connector 401 are positioned such that the terminals for transmitting the image signals overlap when viewed from the widthwise direction. Consequently, the wiring pattern 203 can connect the FFC connectors 202, the FFC connector 401, and the image processing unit 204 in an almost straight line.

In the above description, multiple image reading apparatus (first image reading apparatus 100 and second image reading apparatus 300) are selectively connected to the circuit board 200 of the image forming apparatus 2. However, the apparatuses connected to the circuit board 200 are not limited to image reading apparatus. Furthermore, the circuit board 200 is not limited to being mounted in the image forming apparatus 2. For example, even in a case where the circuit board 200 is mounted in an information processing apparatus such as a computer capable of connecting multiple external devices having the same function, the circuit board 200 can achieve the effects described above.

In the above description, a configuration in which components are mounted on one surface of the circuit board 200 has been described. However, components other than the FFC connectors 202 and 401 may be mounted on the other surface of the circuit board 200. For example, the communication ICs 205 and 405 may be mounted on the other surface of the circuit board 200.

Thus, according to the present disclosure, it is possible to suppress signal quality degradation in a circuit board having multiple connectors.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of priority from Japanese Patent Application No. 2025-040346, filed Mar. 13, 2025, which is hereby incorporated by reference herein in its entirety.

What is claimed is:

1. A circuit board, comprising:
a surface;
a first connector mounted on the surface;
a second connector mounted on the surface; and
a wiring pattern connected to the first connector and the second connector,
wherein a length of the first connector along a first direction is longer than a length of the first connector along a second direction perpendicular to the first direction, each of the first direction and the second direction being parallel to the surface,
wherein a length of the second connector along the first direction is longer than a length of the second connector along the second direction, and
wherein the first connector and the second connector are arranged such that at least a portion of the first connector overlaps at least a portion of the second connector when viewed in projection along the second direction.

2. The circuit board according to claim 1, further comprising a processor mounted on the surface and configured to process a signal transmitted via the first connector or the second connector.

3. The circuit board according to claim 2,
wherein the wiring pattern connects each of the first connector and the second connector to the processor, and
wherein a stub of the wiring pattern in a case where an external cable is connected to the first connector is shorter than a stub of the wiring pattern in a case where an external cable is connected to the second connector.

4. The circuit board according to claim 1, wherein a distance along the second direction from the first connector to an edge of the circuit board is shorter than a distance along the second direction from the second connector to the edge of the circuit board.

5. The circuit board according to claim 3, wherein a communication speed of a signal transmitted via the first connector is higher than a communication speed of a signal transmitted via the second connector.

6. The circuit board according to claim 4, wherein a communication speed of a signal transmitted via the first connector is higher than a communication speed of a signal transmitted via the second connector.

7. An image forming apparatus comprising:
a printing unit configured to form an image on a sheet; and
a circuit board,
wherein the circuit board includes
a surface,
a first connector mounted on the surface,
a second connector mounted on the surface, and
a wiring pattern connected to the first connector and the second connector,
wherein a length of the first connector along a first direction is longer than a length of the first connector along a second direction perpendicular to the first direction, each of the first direction and the second direction being parallel to the surface,
wherein a length of the second connector along the first direction is longer than a length of the second connector along the second direction, and
wherein the first connector and the second connector are arranged such that at least a portion of the first connector overlaps at least a portion of the second connector when viewed in projection along the second direction.

8. An image forming apparatus comprising:
an image reading unit; and
a circuit board connected to the image reading unit via a cable,
wherein the circuit board includes
a surface,
a first connector mounted on the surface,
a second connector mounted on the surface, and
a wiring pattern connected to the first connector and the second connector,
wherein the cable is connected to one of the first connector or the second connector,
wherein a length of the first connector in a first direction along the surface is longer than a length of the first connector in a second direction along the surface, the second direction being perpendicular to the first direction,
wherein a length of the second connector in the first direction is longer than a length of the second connector in the second direction, and
wherein the first connector and the second connector are arranged such that at least a portion of the first connector overlaps at least a portion of the second connector when viewed in projection along the second direction.

9. The image forming apparatus according to claim 8,
wherein the circuit board comprises a processor connected to the image reading unit via the wiring pattern, and
wherein a stub of the wiring pattern in a case where the cable is connected to the first connector is shorter than a stub of the wiring pattern in a case where the cable is connected to the second connector.

10. The image forming apparatus according to claim 8, wherein a distance along the second direction from the first connector to an edge of the circuit board is shorter than a distance along the second direction from the second connector to the edge of the circuit board.

11. The image forming apparatus according to claim 9, wherein a communication speed of a signal transmitted via the first connector is higher than a communication speed of a signal transmitted via the second connector.

12. The image forming apparatus according to claim 10, wherein a communication speed of a signal transmitted via the first connector is higher than a communication speed of a signal transmitted via the second connector.

13. The image forming apparatus according to claim 8,
wherein the first connector comprises a first terminal to which an image signal representing an image of a document read by the image reading unit is input,
wherein the second connector comprises a second terminal to which an image signal representing an image of a document read by the image reading unit is input, and
wherein the first terminal and the second terminal are connected via the wiring pattern.

14. The image forming apparatus according to claim 8, further comprising a printing unit configured to form an image on a sheet,
wherein the circuit board comprises a processor connected to the image reading unit via the wiring pattern and configured to process an image signal acquired by the image reading unit, and
wherein the printing unit is configured to form an image on a sheet based on the image signal processed by the processor.

15. The image forming apparatus according to claim 8, wherein the cable connected to the one of the first connector or the second connector comprises a plurality of conductors bundled together.
